(19) United States
(12) Patent Application Publication
(10) Pub. No.: US 2024/0064933 A1
(43) Pub. Date: Feb. 22, 2024

(54) DETECTION AND DEFLECTION OF FLUID LEAKAGES IN IMMERSION COOLING SYSTEMS

(71) Applicant: OVH, Roubaix (FR)

(72) Inventors: Mohamad HNAYNO, Roubaix (FR); Ali CHEHADE, Moncheaux (FR); Henryk KLABA, Roubaix (FR)

(21) Appl. No.: 18/233,922

(22) Filed: Aug. 15, 2023

(30) Foreign Application Priority Data
Aug. 18, 2022 (EP) 22306240.7
Aug. 29, 2022 (EP) 22306276.1

(51) Int. Cl. H05K 7/20; G01M 3/32

(52) U.S. Cl. CPC H05K 7/20272; H05K 7/20236; G01M 3/3245; G08B 21/182

(57) ABSTRACT

A fluid leakage deflection arrangement for a liquid-cooled rack-mounted electronic processing assembly and a method for deflecting fluid leakages in a liquid-cooled rack-mounted electronic processing assembly are disclosed. The fluid leakage deflection arrangement comprises an immersion case containing a first cooling liquid in which an electronic device of the rack-mounted electronic processing assembly is at least partially submerged therein; and a deflection unit configured to prevent the electronic device from being in contact with a leaking liquid distinct from the first cooling liquid by diverting leaking liquid away from the electronic components.

### CROSS-REFERENCE

The present application claims priority to European Patent Appl. No. 22306240.7, filed Aug. 18, 2022 entitled “Immersion-Cooled Electronic Device and Cooling Monitoring System for Immersion Cooled Electronic Device”, the entirety of which is incorporated herein by reference; and to European Patent Appl. No. 22306276.1 filed Aug. 29, 2022 entitled “Detection and Deflection of Fluid Leakages in Immersion Cooling Systems”, the entirety of which is incorporated by reference herein.

### FIELD OF TECHNOLOGY

The present technology relates to immersion-cooled electronic processing equipment. In particular, the present technology relates to the detection and deflection of fluid leakages in immersion cooling systems servicing electronic processing equipment.

### BACKGROUND

Electronic equipment, for example servers, memory banks, computer disks, and the like, is conventionally grouped in equipment racks. Large data centers and other large computing facilities may contain thousands of racks supporting thousands or even tens of thousands of rack-mounted electronic assemblies containing servers and associated electronic equipment. The racks, including equipment mounted in their backplanes, consume large amounts of electric power and generate significant amounts of heat, that should be quelled or at least dissipated in order to avoid individual electronic component failures and ensure reliable and consistent operations.

Various cooling measures have been implemented to address the heat generated by the rack-mounted assemblies. One such measure provides a direct liquid cooling block configuration, that is deployed in addition to, or in replacement of, traditional forced-air cooling. In this configuration, cooling plates or blocks are configured with internal conduits to accommodate the circulation of cool channelized liquid (e.g., water). These liquid cooling blocks are directly mounted onto heat-generating electronic components, such as processors, to displace heat from the processors into the channelized liquid flowing through the liquid cooling blocks that, in turn, is forwarded towards heat exchangers.

Another cooling measure provides an immersion cooling configuration, in which the heat-generating electronic components of rack-mounted assemblies are submerged in a container that is at least partially filled with a non-conducting cooling fluid, such as, for example, an oil-based dielectric cooling fluid. In this manner efficient thermal contact and heat transfer is achieved between the heat-generating electronic components and the cooling dielectric cooling fluid.

Recently, hybrid liquid cooling systems have been proposed intended to exploit the benefits of both direct liquid cooling block and immersion cooling configurations in order to maximize the overall cooling efficiency of the rack-mounted assemblies. In particular, such liquid cooling systems deploy the liquid cooling blocks directly mounted onto heat-generating electronic components to circulate the cooling channelized liquid in combination with the submergence of the heat-generating electronic components into an immersion dielectric cooling fluid.

However, it has been observed that such liquid cooling systems may be susceptible to certain malfunctions, such as, for example, leakages of the channelized liquid from the coupling components of the liquid cooling block onto the electronic components, the immersion dielectric cooling fluid, and/or other rack-mounted assemblies.

These leakage issues may be particularly problematic, as the channelized cooling liquid may comprise water or other liquids that provide adequate heat transfer performance for channelized cooling but may not be suitable for immersion cooling due to its conductivity and/or corrosive properties of exposed electronic components. For example, if water is used as the channelized cooling liquid, it is likely that the concentration of ions in the water will cause the water to be sufficiently conductive to cause damage to electronic components. And, even if the water is initially distilled or deionized, the concentration of ions will increase as the water is circulated through the channelized cooling system.

As such, there is an interest in developing an arrangement for detecting and deflecting fluid leakages in liquid cooling systems.

It will be appreciated that the subject matter discussed in the background section should not be assumed to be prior art merely based as result of being mentioned in the background section. Similarly, drawbacks indicated in the background section or associated with the subject matter of the background section should not be assumed to have been previously recognized in the prior art. The subject matter in the background section merely represents different approaches.

### SUMMARY

The embodiments and examples of the present disclosure are provided based on developers' understanding of the drawbacks associated with liquid cooling systems experiencing leakage issues of the liquid cooling blocks within a rack-mounted assembly or onto other rack-mounted assemblies.

In accordance with a first broad aspect of the present disclosure, there is provided a fluid leakage deflection arrangement for a liquid-cooled rack-mounted electronic processing assembly, comprising an immersion case containing a first cooling liquid in which an electronic device of the rack-mounted electronic processing assembly is at least partially submerged therein; and a deflection unit configured to prevent the electronic device from being in contact with a leaking liquid distinct from the first cooling liquid by diverting leaking liquid away from the electronic components.

In accordance with a second broad aspect of the present disclosure, there is provided a rack system comprising a plurality of fluid leakage deflection arrangements, the rack system being arranged so as to accommodate a bottom and a top rows of immersion cases disposed on top of one another, the deflection units of the immersion cases of the bottom row being arranged so as deflect leaking liquid emanating from the immersion cases of the top row.

In some examples of the rack system, the deflection unit comprises an overhanging structure fixedly attached to an upper portion of the electronic device.

In some examples of the rack system, the overhanging structure is fixedly attached to an upper portion of a board of the electronic device.

In some examples of the rack system, the overhanging structure of fluid deflection unit incorporates an angular linear cross-sectional profile to downwardly divert fluid leaks away from the electronic device.

In some examples of the rack system, the overhanging structure of fluid deflection unit incorporates a curved cross-sectional profile to downwardly divert fluid leaks away from the electronic device.

In some examples of the fluid leakage deflection arrangement, the fluid leakage deflection arrangement further comprises at least one liquid cooling block directly mounted onto electronic components of the electronic device and configured to internally channel a second cooling liquid, and wherein the deflection unit is configured to shield the electronic device against fluid leaks by the second cooling liquid from the at least one liquid cooling block by diverting the fluid leaks away from the electronic components.

In some examples of the fluid leakage deflection arrangement, the deflection unit comprises an overhanging structure incorporating an angular linear cross-sectional profile to downwardly divert second cooling liquid fluid leaks away from the electronic components.

In some examples of the fluid leakage deflection arrangement, the deflection unit comprises an overhanging structure incorporating a curved cross-sectional profile to downwardly divert second cooling liquid fluid leaks away from the electronic components.

In some examples of the fluid leakage deflection arrangement, the deflection unit incorporates grooved channels on an upper surface thereof to facilitate the diverting of the second cooling liquid fluid leaks away from the electronic components.

In some examples of the fluid leakage deflection arrangement, the deflection unit is fixedly attached to the at least one liquid cooling block.

In some examples of the fluid leakage deflection arrangement, the fluid leakage deflection arrangement further comprises one or more sensors, disposed within the immersion case, and configured to measure a level of at least one physical/chemical property of the first cooling liquid to detect a presence of a leaking liquid in the immersion case and configured to provide signals reporting the same, and an electrical power controller communicatively coupled to a power distribution unit (PDU) supplying electric power to the rack-mounted electronic processing assembly and communicatively coupled to the one or more sensors, the electrical power controller configured to receive, assess, and execute commands based on the reported signals from the one or more sensors.

In some examples of the fluid leakage deflection arrangement, the measurement of the at least one physical/chemical property of the first cooling liquid to detect a presence of a presence of a leaking liquid leaking in the immersion case comprises measuring at least one of temperature data, conductivity data, viscosity data, and density data.

In some examples of the fluid leakage deflection arrangement, upon assessing the received reporting signals, the electrical power controller executes commands to issue at least one of the following instructions: (i) transmit a normal operations message based on the reported property levels being within an acceptable threshold level; (ii) transmit a maintenance check message based on the reported property levels being close to a limit of the acceptable threshold level; and (iii) transmit a shutdown alert message and issue instructions to disconnect the electrical power supplied by the PDU to the rack-mounted assembly based on the reported property levels exceeding the acceptable threshold level.

In accordance with a third broad aspect of the present disclosure, there is provided a method of deflecting fluid leakages in a liquid-cooled rack-mounted electronic processing assembly (104). The method comprises partially submerging an electronic device of the rack-mounted electronic processing assembly within a first cooling liquid contained by an immersion case and providing a deflection unit configured to shield the electronic device against fluid leaks that cause the immersion case to receive a leaking liquid distinct from the first cooling liquid, by diverting the fluid leaks away from the electronic components.

In some examples of the method, the deflection unit comprises an overhanging structure incorporating an angular linear cross-sectional profile to downwardly divert fluid leaks away from the electronic components.

In some examples of the method, the deflection unit comprises an overhanging structure incorporating a curved cross-sectional profile to downwardly divert fluid leaks away from the electronic components.

In some examples of the method, the deflection unit comprises incorporates grooved channels on an upper surface thereof to facilitate the diverting of the fluid leaks away from the electronic components.

In some examples of the method, the method further comprises mounting at least one liquid cooling block onto electronic components of the electronic device, the at least one liquid cooling block configured to internally channel a second cooling liquid therethrough; and wherein providing a deflection unit comprises fixedly attaching the deflection unit to the at least one liquid cooling block to shield the electronic device against fluid leaks by the second cooling liquid from the at least one liquid cooling block.

In some examples of the method, the method further comprises accommodating the liquid-cooled rack-mounted electronic processing assembly in a rack system, the rack system being configured to accommodate a plurality of liquid-cooled rack-mounted electronic processing assemblies on horizontal racking shelves, the deflection unit being configured to shield the electronic device against fluid leaks from rack-mounted electronic assemblies disposed on uppers horizontal racking shelves of the rack system.

In some examples of the method, the deflection unit comprises an overhanging structure fixedly attached to an upper portion of the electronic device.

In some examples of the method, the overhanging structure is fixedly attached to an upper portion of a board of the electronic device.

In the context of the present specification, unless expressly provided otherwise, a computer system may refer, but is not limited to, an “electronic device”, an “operation system”, a “system”, a “computer-based system”, a “controller unit”, a “monitoring device”, a “control device” and/or any combination thereof appropriate to the relevant task at hand.

In the context of the present specification, unless expressly provided otherwise, the expression “computer-readable medium” and “memory” are intended to include media of any nature and kind whatsoever, non-limiting examples of which include RAM, ROM, disks (CD-ROMs, DVDs, floppy disks, hard disk drives, etc.), USB keys, flash memory cards, solid state-drives, and tape drives. Still in the context of the present specification, “a” computer-readable medium and “the” computer-readable medium should not be construed as being the same computer-readable medium. To the contrary, and whenever appropriate, “a” computer-readable medium and “the” computer-readable medium may also be construed as a first computer-readable medium and a second computer-readable medium.

In the context of the present specification, unless expressly provided otherwise, the words “first”, “second”, “third”, etc. have been used as adjectives only for the purpose of allowing for distinction between the nouns that they modify from one another, and not for the purpose of describing any particular relationship between those nouns.

Implementations of the present technology each have at least one of the above-mentioned objects and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

These and other features, aspects and advantages of the present technology will become better understood with regard to the following description, appended claims and accompanying drawings where:

FIG. 1 depicts a perspective view of a rack system housing liquid cooled rack-mounted assemblies, in accordance with the examples of the present disclosure;

FIG. 2 depicts a schematic functional diagram of a fluid leakage detection and deflection arrangement for a liquid-cooled rack-mounted assembly, in accordance with the examples of the present disclosure;

FIG. 3 depicts a block diagram configuration of a fluid deflection structure to individually shield electronic processing components of a liquid-cooled rack-mounted assembly from fluid leakages, in accordance with the examples of the present disclosure;

FIGS. 4A, 4B depict cross-sectional and perspective views of the fluid deflection structure, in accordance with the examples of the present disclosure; and

FIG. 5 depicts a block diagram of a fluid deflection arrangement for shielding an entire electronic device from fluid leakages, in accordance with the examples of the present disclosure.

It will be appreciated that, unless otherwise explicitly specified herein, the representative drawings are not to scale.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements that, although not explicitly described or shown herein, nonetheless embody the principles of the present technology.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative systems embodying the principles of the present technology.

With these fundamental principles in place, we will now consider some non-limiting examples to illustrate various implementations of aspects of the present disclosure.

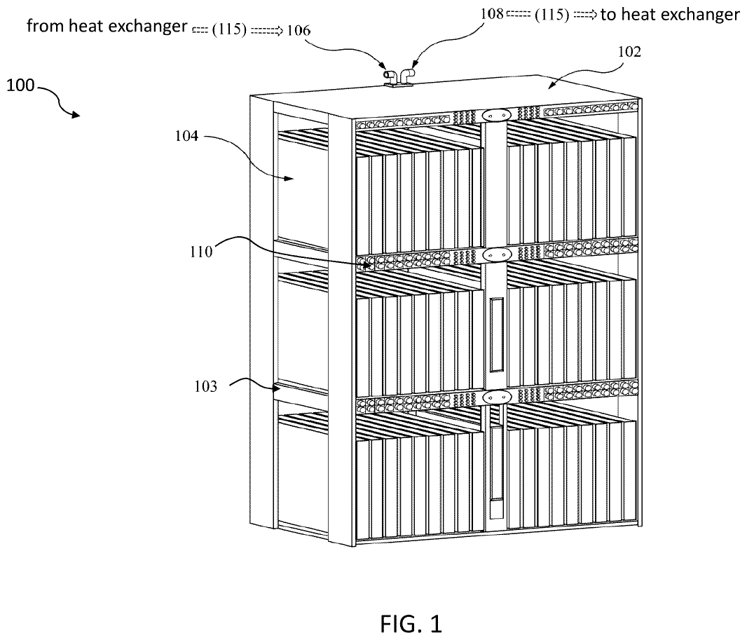

FIG. 1 illustrates a perspective view of a rack system 100 for housing numerous liquid cooled rack-mounted electronic assemblies 104 comprising an electronic device 120 (e.g., server) and associated electronic components 122, in accordance with the nonlimiting examples of the present disclosure. As shown, the rack system 100 includes a rack frame 102, racking shelves 103, rack-mounted electronic assemblies 104, a power distribution unit (PDU) 110, a rack liquid cooling inlet conduit 106, and a rack liquid cooling outlet conduit 108.

The racking shelves 103 are configured to accommodate the rack-mounted electronic assemblies 104 onto the rack frame 102, in which the electronic assemblies 104 may be oriented vertically with respect to the rack frame 102 in order to maximize the number of rack-mounted assemblies 104 housed within the rack frame 102. In some examples, guide members (not shown) may be incorporated on racking shelves 103 to slidably guide the rack-mounted assemblies 104 into position during racking and de-racking operations.

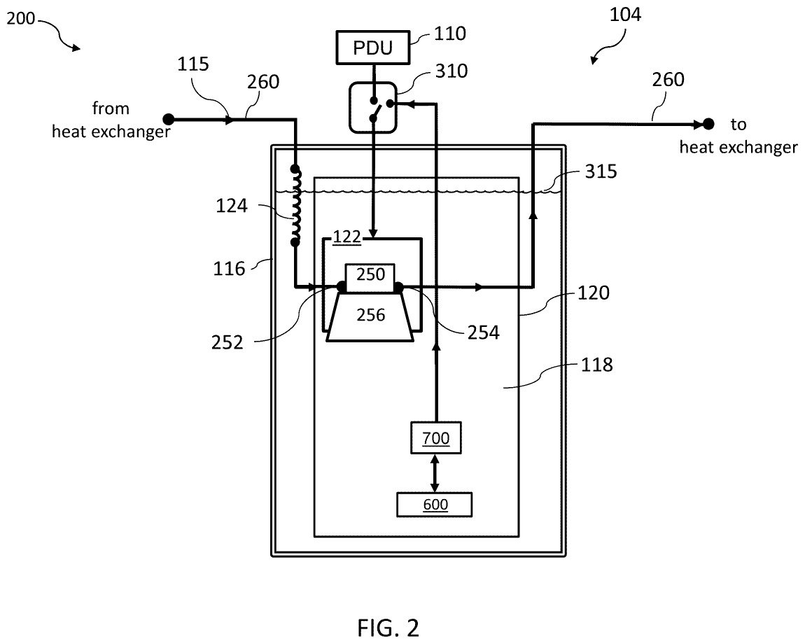

The rack liquid cooling inlet conduit 106 is configured to receive a cooling liquid 115 from an external source (e.g., heat exchanger) that is channely routed to cooling blocks 250 (as shown in FIG. 2) and are directly mounted onto electronic components 122 (as shown in FIG. 2) of the rack-mounted electronic assemblies 104. In turn, the channeled cooling liquid 115 of the cooling blocks 250 that is subjected to the heat generated by the electronic components 122 is subsequently routed to the external source for thermal cooling reconditioning.

The PDU 110 is configured to controllably supply electrical power to the rack-mounted electronic assemblies 104 electronic components 122 (as shown in FIG. 2). As described in greater detail below, the supply of electrical power by the PDU 110 is monitored and controlled based on a power controller 700 and associated sensors 600 that are communicatively coupled to the PDU 110.

It should be appreciated that rack system 100 may include other operational components, such as, for example, heat exchangers, cables, connectors, tubing constructs, pumps, and the like. However, such components have been omitted from FIG. 1 for clarity and tractability purposes of the general inventive concepts provided by the disclosed examples.

FIG. 2 depicts a schematic diagram of a fluid leakage detection and deflection arrangement 200 for a liquid cooled rack-mounted electronic assembly 104, in accordance with the nonlimiting examples of the present disclosure. As shown, the liquid cooled rack-mounted electronic assembly 104 incorporates an electronic device 120 that includes one or more electronic processing components 122 (only one of which is illustrated in FIG. 2 for clarity) mounted on an electronic board 118. In nonlimiting examples, the electronic device 120 may embody a computer server, such as, for example, a Dell™ PowerEdge™ Server running a Microsoft™ Windows Server™ operating system. It will be appreciated, however, that electronic device 120 may be implemented in any other suitable hardware, software, and/or firmware, or a combination thereof.

In the nonlimiting examples provided by the fluid leakage detection and deflection arrangement 200, the liquid cooled rack-mounted electronic assembly 104 incorporates a liquid immersion cooling configuration in combination with a direct liquid cooling block configuration. The liquid immersion cooling configuration deploys an immersion cooling case 116 containing a volume of a first cooling liquid 315, such as, for example, a dielectric cooling fluid. The electronic board 118 comprising the electronic device 120 and associated electronic processing components 122 are at least partially submerged in the immersion cooling fluid 315 for ambient cooling purposes thereof.

The electronic processing components 122 of the electronic device 120 are additionally cooled by a direct liquid cooling block configuration that channels a second cooling liquid 115 therethrough. The direct liquid cooling block configuration deploys one or more liquid cooling blocks 250 (only one of which is illustrated in FIG. 2 for clarity) that are directly mounted onto the electronic processing components 122 of the electronic device(s) 120 for optimal thermal transfer. The channelized second cooling liquid 115 may comprise any combination of water, alcohol, glycol, or any other suitable liquid capable of sustaining adequate cooling temperatures.

As noted above, the liquid cooling block 250 incorporates an internal conduit to accommodate the circulation of the channelized second cooling liquid 115 therethrough that serves to absorb and extract the heat generated by the electronic processing components 122. The internal conduit of liquid cooling block 250 may be configured to embody various formations, such as, for example, snake-like, zigzag, and/or looped configurations, etc. to maximize the surface area for heat absorption potential of the channelized second cooling liquid 115 flowing through the cooling block 250.

It should be appreciated that the direct mounting of the liquid cooling blocks 250 onto the electronic processing components 122 is meant to encompass configurations in which thermal pastes or thermally conductive film materials are applied between a surface of the electronic component 122 and an interfacing surface of the liquid cooling block 250.

Returning to the arrangement 200 of FIG. 2, the channelized second cooling liquid 115 may be supplied by an external source, such as, for example, from a heat exchanger or dry cooler (not shown) to the liquid cooling inlet conduit 106 of rack system 100 (see, FIG. 1) that, in turn, forwards the cooling liquid 115 via a channelized liquid loop 260, to an input side of a serpentine convection coil 124. The serpentine convection coil 124 may be structured with multiple hollow-channel coils to provide a high surface area exposure relative to the the dielectric cooling fluid 315 while also maintaining compact overall length and width dimensions. With this structure, the serpentine convection coil 124 operates to internally convey the circulating channelized second cooling liquid 115 that operates to both, cool the ambient the immersion dielectric cooling fluid 315 as well as forward the channelized cooling liquid 115 to the liquid cooling block 250 in direct thermal contact with the electronic processing components 122.

As shown, the liquid cooling block 250 is configured with a liquid inlet 252, fluidly connected to an output side of the serpentine convection coil 124, for receiving the channelized second cooling liquid 115 from the serpentine convection coil 124. The received channelized second cooling liquid 115 is then circulated through by the internal conduit of the liquid cooling block 250. The liquid cooling block 250 further incorporates a liquid outlet 254 for discharging the second cooling liquid 115 warmed by the electronic components 122 to a heat exchanger or dry cooler (not shown), via the channelized liquid loop 260, for thermal cooling reconditioning.

The arrangement 200 may also implement a fluid deflection unit 256 fixedly attached to the liquid cooling block 250. As explained in greater detail below, the fluid deflection unit 256 operates to shield the electronic processing components 122 from fluid leakages stemming from the liquid cooling block 250 by diverting such leakages away from the electronic processing components 122. In other words, the fluid deflection unit 256 prevents the electronic components 122 from being in contact with a leaking liquid distinct from the cooling fluid 315 by diverting leaking liquid away from the electronic processing components 122.

The arrangement 200 may further comprise an electric power controller 700, a switching device 310, and one or more measurement sensors 600 communicatively coupled to the controller 500. The electric power controller 700 may be mounted onto the electronic board 118 of electronic device 120 and may be operatively coupled to the PDU 110 via the switching device 310. In various examples, the switching device 310 may be integrated within the electronic device 120 or may be located outside the electronic device 120 (e.g. along a power line that supplies electric power from the PDU 110 to the electronic device 120). The power controller 700 is configured to receive signals from the communicatively coupled measurement sensors 600 and execute messages and/or command instructions in response to the received measurement signals.

In various nonlimiting examples, the measurement sensors 600 are disposed at a lower portion of the electronic board 118 and are configured to detect certain properties of the fluid settling at the lower portion of the board 118. That is, the channelized cooling liquid 115 of the cooling blocks 250 typically has a higher density than the density of the immersion first cooling fluid 315. As a result, in case of leakages by the cooling blocks 250, the channelized second cooling liquid 115 will sink to a lower portion of the immersion case 116. In some examples of the present technology, the measurement sensors 600 are mounted on the fluid deflection unit 256. In those examples, the measurement sensors 600 are thus disposed near potential leakages that could occur at cooling blocks 250.

Correspondingly, the measurement sensors 600 are disposed along a lower portion of the immersion case 116 to detect the presence of leaked channelized second cooling liquid 115 based on the measurement of certain properties of the fluid settling at the lower portion of the immersion case 116. As such, the measurement sensors 600 may be configured to measure one or more physical/chemical properties and the levels of such properties of the fluid along the lower portion the immersion case 116 in order to detect the presence of the channelized second cooling liquid 115. The detection of the physical/chemical properties and associated levels of the lower portion fluid of immersion case 116 may include, for example, measuring temperature, conductivity, viscosity, density, etc.

Upon the measurement sensors 600 detecting that the physical/chemical properties and/or associated levels indicate the presence of the channelized second cooling liquid 115 within the immersion case 116, the sensors 600 communicate measurement signals reporting the same to the electric power controller 700. In turn, the controller 500 operates to compare the reported measurement signals providing the physical/chemical property levels against predetermined acceptable threshold levels.

In certain nonlimiting examples, the electric power controller 700 is configured to provide command instructions and messaging signals comprising, inter alia: (a) normal operations message in response to sensors 600 reporting that the property levels are within acceptable threshold levels; (b) maintenance check message in response to sensors 600 reporting that the property levels are close to exceeding the threshold levels; and (c) a shutdown alert message along with command instructions to open the switching device 310 to disconnect power supplied by the PDU 110 to the corresponding rack-mounted assembly 104 or to an entire shelf 103 of rack-mounted assemblies 104. In some examples, the switching device is part of the electronic device 120. In these examples, the electric power controller 700 may communicate with the electronic device 120 and cause the switching device 310 to electrically disconnect the electronic device 120 from the PDU 110.

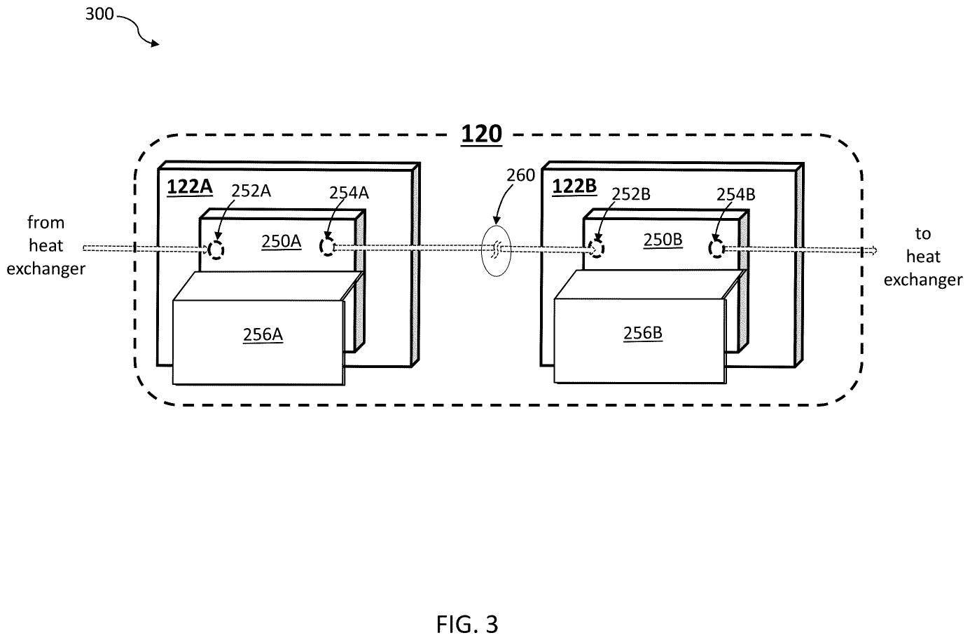

As noted above, the fluid leakage monitoring and deflection arrangement 200 may incorporate a fluid deflection unit 256 mounted onto individual liquid cooling blocks 250 to shield associated electronic processing components 122 from leakages of the channelized second cooling liquid 115 stemming from the liquid cooling block 250. To this end, FIG. 3 depicts a configuration 300 deploying liquid cooling block fluid deflection units 256A, 256B configured to shield related electronic processing components 122A, 112B from fluid leakages, in accordance with the examples of the present disclosure.

As shown, the liquid cooling block fluid deflection units 256A, 256B are fixedly attached onto respective liquid cooling blocks 250A, 250B which, in turn, are directly mounted on electronic processing components 122A, 122B of electronic device 120 (e.g., server). As noted above, the liquid cooling blocks 250A, 250B receive the channelized second cooling liquid 115 via a channelized liquid loop 260 and internally channel the second cooling liquid 115 therethrough to dissipate the heat generated by related electronic processing components 122A. Depending on various configurations supported by the disclosed examples, the channelized second cooling liquid 115 may be forwarded to a subsequent liquid cooling block 250B via the channelized liquid loop 260 (as shown) or may be directed back to a cooling liquid source (e.g., heat exchanger) for cooling reconditioning processing.

The attachment of the fluid deflection units 256A, 256B to the respective liquid cooling blocks 250A, 250B may be achieved by any suitable means, such as, for example, welding of the fluid deflection units 256A, 256B to the respective liquid cooling blocks 250A, 250B, fastening one or more fasteners (e.g. screws) through opening defined in the fluid deflection units 256A, 256B to the liquid cooling blocks 250A, 250B or to a plate welded thereon, or any other suitable manner.

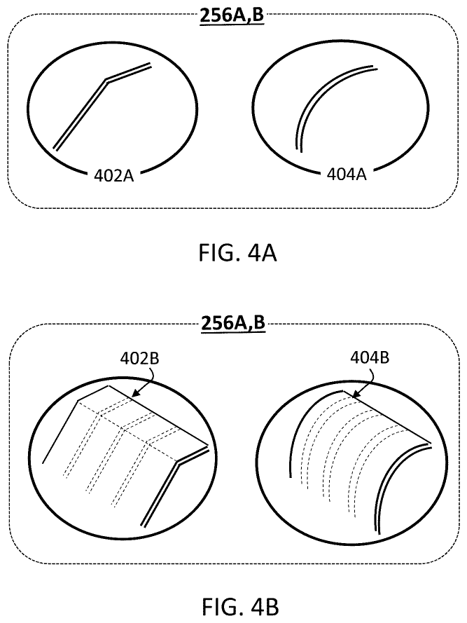

The fluid deflection units 256A, 256B operate to shield the electronic processing components 122A, 122B from second cooling liquid 115 leakages stemming from the liquid cooling blocks 250A, 250B by incorporating an overhanging structure that diverts such leakages away from the electronic processing components 122A, 122B. To this end, FIGS. 4A, 4B depict cross-sectional and surface perspective views of the structure of the fluid deflection units 256A, 256B, in accordance with the examples of the present disclosure.

As shown, FIG. 4A depicts nonlimiting examples of cross-sectional profiles of the structure of fluid deflection units 256A, 256B. In one example, the fluid deflection units 256A, 256B may embody an overhanging structure incorporating an angular linear cross-sectional profile 402A configured to downwardly divert fluid leakages away from electronic processing components 122A, 122B. In an alternative example, the fluid deflection units 256A, 256B may embody an overhanging structure incorporating a curved cross-sectional profile 402A configured to downwardly divert fluid leakages away from electronic processing components 122A, 122B.

FIG. 4B depicts nonlimiting examples of perspective top surface views of the structure of the fluid deflection units 256A, 256B. As shown, the top surfaces of the fluid deflection units 256A, 256B may further incorporate grooved channels 402B, 404B along the angular linear profile 402A and the curved cross-sectional profile 404A, respectively. The grooved channels 402B, 404B are configured to expedite the guidance of diverting fluid leakages away from electronic processing components 122A, 122B.

In this manner, the fluid leakage detection and deflection arrangement 200 is capable of detecting fluid leakages within an electronic processing assembly 104 as well as divert such leakages stemming from the liquid cooling block 250 away from electronic components 122 within the electronic processing assembly 104.

However, as indicated above by FIG. 1, rack system 100 comprises a plurality of vertically-disposed rows of horizontal racking shelves 103, in which each row of the horizontal racking shelves 103 accommodates the placement of multiple rack-mounted electronic assemblies 104. As such, it will be appreciated that any fluid leakages from rack-mounted electronic assemblies 104 disposed on uppers row of rack system 100 may spill over onto electronic assemblies 104 disposed on lower rows of rack system 100.

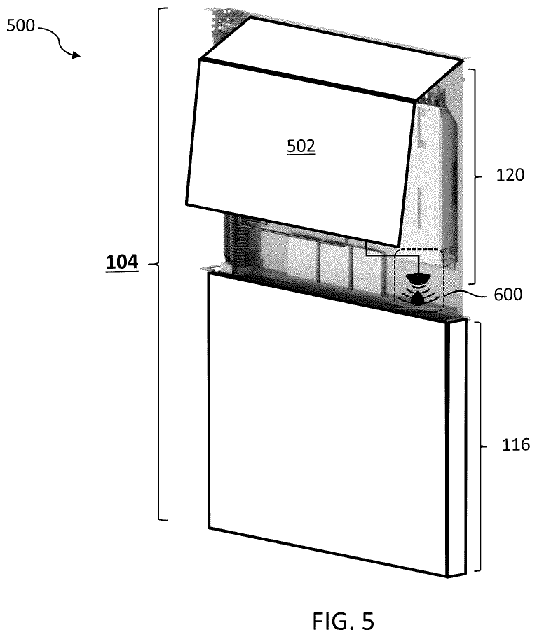

To this end, FIG. 5 depicts a block diagram of a fluid deflection arrangement 500 for shielding an entire rack-mounted electronic processing assembly 104 from fluid leakages stemming from upper rack-mounted electronic assemblies 104 of rack system 100, in accordance with the examples of the present disclosure. For clarity, FIG. 5 illustrates the rack-mounted electronic processing assembly 104 in an open withdrawn position to indicate the separation of the electronic device 120 (e.g., server) from the immersion case 116.

As shown, the fluid deflection arrangement 500 incorporates a fluid deflection unit 502 comprising an overhanging structure fixedly attached to an upper portion of the electronic device 120. The attachment of the fluid deflection unit 502 to the electronic device 120 may be achieved by any suitable means, such as, for example, by fastening fasteners (e.g. screws) through openings defined in the fluid deflection unit 502 and in the board 118. As another example, the board 118 may define pins on an upper portion thereof (e.g. an upper edge thereof) such that said pins may be inserted in openings defined in the fluid deflection unit 502. The pins may be adjusted (e.g. bended) to maintain connection between the fluid deflection unit 502 and the board 118. Other attachment means are contemplated in alternative examples.

Similar to the nonlimiting configurations of fluid deflection units 256A, 256B noted above, the overhanging structure of fluid deflection unit 502 may embody an angular linear cross-sectional profile or a curved cross-sectional profile to downwardly divert fluid leakages away from the electronic device 120. Moreover, the top surface of the overhanging structure of fluid deflection unit 502 may also embody grooved channels configured to expedite the guidance of diverting fluid leakages away from the electronic device 120. The fluid deflection units 256A, 256B thus divert leaking fluid within the immersion case 116, while the fluid deflection unit 502 diverts leaking fluid outside the immersion case 116. The fluid deflection units 256A, 256B and the fluid deflection unit 502 may be combined in some examples of the present technology such that a given immersion case 116 is operably connected to a fluid deflection unit 502, and the electronic device 120 enclosed in the immersion case 116 is prevent from being in contact with a leaking liquid distinct from the cooling liquid 315 by fluid deflection units 256A, 256B.

Equally notable, the fluid deflection arrangement 500 may also incorporate measurement sensors 600 disposed along a lower portion of the immersion case 116 to detect the presence of leaked channelized second cooling liquid 115 based on certain properties of the fluid settling at a lower portion of the immersion case 116. As noted above, the measurement sensors 600 are communicatively coupled to power controller 700 (not shown) and are configured to determine one or more physical/chemical properties and report the levels of such properties to power controller 700. Depending on the detected property levels reported by the measurement sensors 600, the power controller 700 may provide command instructions and messaging signals comprising, inter alia: (a) normal operations message in response to sensors 600 reporting that the property levels are within acceptable threshold levels; (b) maintenance check message in response to sensors 600 reporting that the property levels are close to exceeding the threshold levels; and (c) a shutdown alert message along with instructions to open the switching device 310 to disconnect power supplied by the PDU 110 to the electronic device 120 of the corresponding rack-mounted assembly 104 or to an entire shelf 103 of rack-mounted assemblies 104.

In this manner, the fluid deflection arrangement 500 is capable of detecting fluid leakages within an electronic processing assembly 104 as well as shielding an entire rack-mounted electronic processing assembly 104 from such leakages stemming from upper rack-mounted electronic assemblies 104 of rack system 100.

With this said, it will be understood that, although the embodiments and examples presented herein have been described with reference to specific features and structures, various modifications and combinations may be made without departing from the disclosure. The specification and drawings are, accordingly, to be regarded simply as an illustration of the discussed implementations, embodiments or examples and their principles as defined by the appended claims, and are contemplated to cover any and all modifications, variations, combinations or equivalents that fall within the scope of the present disclosure.

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

What is claimed is:

1. A fluid leakage deflection arrangement for a liquid-cooled rack-mounted electronic processing assembly, comprising:
an immersion case containing a first cooling liquid in which an electronic device of the rack-mounted electronic processing assembly is at least partially submerged therein, the electronic device comprising electronic components;
a liquid cooling block mounted on the electronic device and in thermal contact with the electronic components and incorporating an internal conduit to accommodate the circulation of a channelized cooling liquid to absorb and extract thermal energy from the electronic components; and
a deflection unit configured to prevent the electronic device from being in contact with leaking channelized cooling liquid by diverting leaking channelized cooling liquid away from the electronic components.

2. A rack system comprising a plurality of fluid leakage deflection arrangements in accordance with claim 1, the rack system being arranged so as to accommodate a bottom and a top rows of immersion cases disposed on top of one another, the deflection units of the immersion cases of the bottom row being arranged so as deflect leaking liquid emanating from the immersion cases of the top row.

3. The rack system of claim 2, wherein the deflection unit comprises an overhanging structure fixedly attached to an upper portion of the electronic device.

4. The rack system of claim 3, wherein the overhanging structure is fixedly attached to an upper portion of a board of the electronic device.

5. The arrangement of claim 1, wherein the deflection unit is fixedly attached to the liquid cooling block.

6. The arrangement of claim 1, further comprising:
one or more sensors, disposed within the immersion case, and configured to measure a level of at least one physical/chemical property of the first cooling liquid to detect a presence of a leaking liquid in the immersion case and further configured to provide signals reporting the same; and
an electrical power controller communicatively coupled to a power distribution unit (PDU) that supplies electric power to the rack-mounted electronic processing assembly and is communicatively coupled to the one or more sensors, the electrical power controller configured to receive, assess, and execute commands based on the reported signals from the one or more sensors.

7. The arrangement of claim 6, wherein the measurement of the at least one physical/chemical property of the first cooling liquid to detect a presence of a leaking liquid leaking in the immersion case comprises measuring at least one of temperature data, conductivity data, viscosity data, and density data.

8. The arrangement of claim 7 wherein, upon assessing the received reporting signals, the electrical power controller executes commands to issue at least one of the following instructions:
(i) transmit a normal operations message based on the reported property levels being within an acceptable threshold level;
(ii) transmit a maintenance check message based on the reported property levels being close to a limit of the acceptable threshold level; and
(iii) transmit a shutdown alert message and issue instructions to disconnect the electrical power supplied by the PDU to the rack-mounted assembly based on the reported property levels exceeding the acceptable threshold level.

9. A method of deflecting fluid leakages in a liquid-cooled rack-mounted electronic processing assembly, comprising:
partially submerging an electronic device of the rack-mounted electronic processing assembly within a first cooling liquid contained by an immersion case, the electronic device comprising electronic components;
mounting a liquid cooling block on the electronic device that is in thermal contact with the electronic components, the liquid cooling block incorporating an internal conduit to accommodate the circulation of a channelized cooling liquid to absorb and extract thermal energy from the electronic components; and
providing a deflection unit configured to shield the electronic device against fluid leaks that cause the immersion case to receive leaking channelized cooling liquid, by diverting the fluid leaks away from the electronic components.

10. The method of claim 9, wherein the deflection unit incorporates grooved channels on an upper surface thereof to facilitate the diverting of the fluid leaks away from the electronic components.

11. The method of claim 9, wherein the providing of deflection unit further comprises fixedly attaching the deflection unit to the liquid cooling block to shield the electronic device against fluid leaks by the channelized cooling liquid from the liquid cooling block.

12. The method of claim 9, further comprising:
accommodating the liquid-cooled rack-mounted electronic processing assembly in a rack system, the rack system being configured to accommodate a plurality of liquid-cooled rack-mounted electronic processing assemblies on horizontal racking shelves;
wherein, the deflection unit is configured to shield the electronic device against fluid leaks from rack-mounted electronic assemblies disposed on uppers horizontal racking shelves of the rack system.

13. The method of claim 12, wherein the deflection unit comprises an overhanging structure fixedly attached to an upper portion of the electronic device.

14. The method of claim 13, wherein the overhanging structure is fixedly attached to an upper portion of a board of the electronic device.
